(19) United States
(12) Patent Application Publication
(10) Pub. No.: US 2026/0056137 A1
(43) Pub. Date: Feb. 26, 2026

(54) METHOD OF MONITORING SUBSTRATE CHUCK CLEANLINESS USING THE SPREAD FRONT

(71) Applicant: CANON KABUSHIKI KAISHA, Tokyo (JP)

(72) Inventors: Wei Zhang, Austin, TX (US); Zhengmao Ye, Austin, TX (US); Kenneth Aird, Austin, TX (US)

(21) Appl. No.: 18/814,334

(22) Filed: Aug. 23, 2024

(51) Int. Cl. G01N 21/956; G01N 21/95; G03F 7/00; H01L 21/67

(52) U.S. Cl. CPC G01N 21/956; G01N 21/9501; H01L 21/67288; G03F 7/0002

(57) ABSTRACT

A method for monitoring substrate chuck flatness by monitoring a spread front using a spread camera to detect a change in flatness of a substrate chuck in real time. The method includes obtaining multiple fluid spread image sequences containing interference fringes that appear during a film shaping process for a series of substrates, determining locations of outliers based on radial distances of the interference fringes for each substrate from the series of substrates and applying a corrective action to the substrate chuck when there are repeating outliers at similar locations across multiple substrates from the series of substrates.

### BACKGROUND

### Field of Art

The present disclosure relates to a method of monitoring wafer chuck cleanliness using the spread front. In particular, the method is directed to monitoring an image of the spread front for distortion among the interference fringes during a nanoimprint lithography or inkjet adaptive planarization in real-time so that corrective actions to clean the wafer chuck may be implemented.

### Description of the Related Art

Planarization techniques are useful in fabricating semiconductor devices. For example, the process for creating a semiconductor device includes repeatedly adding and removing material to and from a substrate. This process can produce a layered substrate with an irregular height variation (i.e., topography), and as more layers are added, the substrate height variation can increase. The height variation has a negative impact on the ability to add further layers to the layered substrate. Separately, semiconductor substrates (e.g., silicon wafers) themselves are not always perfectly flat and may include an initial surface height variation (i.e., topography). One method of addressing this issue is to planarize the substrate between layering steps. Various lithographic patterning methods benefit from patterning on a planar surface. In ArFi laser-based lithography, planarization reduces the impact of depth of focus (DOF) limitations, and improves critical dimension (CD), and critical dimension uniformity. In extreme ultraviolet lithography (EUV), planarization improves feature placement and reduces the impact of DOF limitations. In nanoimprint lithography (NIL) planarization improves feature filling and CD control after pattern transfer.

A planarization technique sometimes referred to as inkjet-based adaptive planarization (IAP) involves dispensing a variable drop pattern of polymerizable material between the substrate and a superstrate, where the drop pattern varies depending on the substrate topography. A superstrate is then brought into contact with the polymerizable material after which the material is polymerized on the substrate, and the superstrate removed. Improvements in planarization techniques, including IAP techniques, are desired for improving, e.g., whole wafer processing and semiconductor device fabrication.

During the nanoimprint lithography (NIL) or inkjet-based adaptive planarization (IAP) process, particles or other contamination sources can land onto the wafer chuck. These unintended events may change the wafer chuck flatness which significantly affects the overlay in NIL and defect quality in NIL and IAP.

There is a need in the art for a method of monitoring such events in real time so that corrective actions such as wafer chuck cleaning can be performed promptly. There is also a need in the art for determining whether the flatness change event is on the substrate front side or back side, and if it is permanent or temporary.

### SUMMARY

The present disclosure is directed to a method for monitoring substrate chuck flatness by monitoring a spread front using a spread camera to detect a change in flatness of a substrate chuck in real-time. Monitoring the spread front image(s) in real-time enables determining the exact location of the flatness change in the substrate chuck and determine if such a change is permanent or temporary in order to implement a corrective action. The method includes obtaining multiple fluid spread image sequences containing interference fringes that appear during a film shaping process for a series of substrates, determining locations of outliers based on radial distances of the interference fringes for each substrate from the series of substrates and applying a corrective action to the substrate chuck when there are repeating outliers at similar locations across multiple substrates from the series of substrates.

These and other objects, features, and advantages of the present disclosure will become apparent upon reading the following detailed description of exemplary embodiments of the present disclosure, when taken in conjunction with the appended drawings, and provided claims.

### BRIEF DESCRIPTION OF DRAWINGS

So that features and advantages of the present disclosure can be understood in detail, a more particular description of embodiments of the disclosure may be had by reference to the embodiments illustrated in the appended drawings. It is to be noted, however, that the appended drawings only illustrate typical embodiments of the disclosure, and are therefore not to be considered limiting of its scope, for the disclosure may admit to other equally effective embodiments.

FIG. 1 is a schematic diagram illustrating an example planarization system in accordance with an aspect of the present disclosure.

FIGS. 2A to 2C illustrate a schematic cross section of an example planarization process in accordance with an aspect of the present disclosure.

FIG. 3 is a cross-sectional view illustrating a state of bringing a superstrate/mold/template and formable material into contact with each other.

FIGS. 4A to 4F are drawings illustrating a contact area between the mold/template and the formable material and an interference fringe in the periphery thereof.

FIG. 5 is an explanatory drawing illustrating a phenomenon in which the interference fringe is seen in the periphery of the contact area.

FIG. 6 is a drawing illustrating a contact state among the detected interference fringe, the template, and the substrate with a foreign particle between the template and the substrate.

FIG. 7 is a flowchart outlining the steps for monitoring substrate chuck flatness in real-time in accordance with an example embodiment.

FIG. 8 is a flowchart detailing the step of calculating substrate chuck flatness change from FIG. 7 in accordance with an example embodiment.

FIGS. 9A-9E illustrate the relationship of the radial distance with respect to the angle of a non-concentric circle and the interference fringes in accordance with an example embodiment.

FIG. 10 is a flowchart detailing the comparison step illustrated in the flow chart of FIG. 8 in accordance with an example embodiment.

Throughout the figures, the same reference numerals and characters, unless otherwise stated, are used to denote like features, elements, components or portions of the illustrated embodiments. Moreover, while the subject disclosure will now be described in detail with reference to the figures, it is done so in connection with the illustrative exemplary embodiments. It is intended that changes and modifications can be made to the described exemplary embodiments without departing from the true scope and spirit of the subject disclosure as defined by the appended claims.

### DETAILED DESCRIPTION

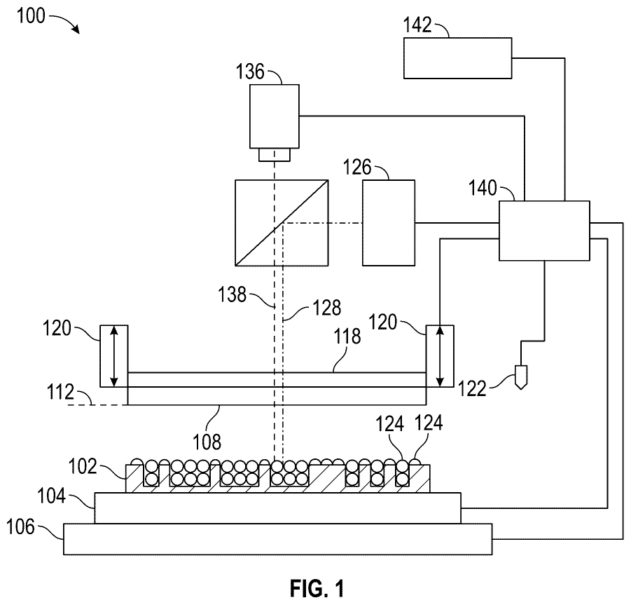

FIG. 1 illustrates an example system for shaping a film (for example planarization) in accordance with an aspect of the present disclosure. The shaping system 100 is used to shape (for example planarize or nanoimprint) a film on a substrate 102 on nanometer length scales. Non-limiting examples of shaping system 100 are a nanoimprint lithography system and an inkjet adaptive planarization system. The substrate 102 or wafer may be coupled to a substrate chuck 104. The term substrate chuck 104 may be used interchangeably throughout the specification with the term wafer chuck. The substrate chuck 104 may be but is not limited to a vacuum chuck, pin-type chuck, groove-type chuck, electrostatic chuck, electromagnetic chuck, and/or the like.

The substrate 102 and the substrate chuck 104 may be further supported by a substrate positioning stage 106. The substrate positioning stage 106 may provide translational and/or rotational motion along one or more of the x-, y-, z-, θ-, ψ, and φ-axes. The substrate positioning stage 106, the substrate 102, and the substrate chuck 104 may also be positioned on a base (not shown). The substrate positioning stage may be a part of a positioning system.

Spaced apart from the substrate 102 is a superstrate 108 (also referred herein as a plate) having a working surface 112 facing substrate 102. The superstrate 108 may be formed from materials including, but not limited to, fused silica, quartz, silicon, organic polymers, siloxane polymers, borosilicate glass, fluorocarbon polymers, metal, hardened sapphire, ceramic, glass, and/or the like. In an embodiment the superstrate is readily transparent to UV light. The working surface 112 is generally of the same area size or slightly smaller than the surface of the substrate 102. The working surface 112 can be substantially featureless in which case the superstrate 108 is used for planarization. The working surface 112 can also include a pattern of recesses and depressions which can be used to pattern a film on the substrate 102. The superstrate 108 can also be smaller than the substrate and used in a step and repeat manner on the substrate 102. When the superstrate 108 has a working surface 112 that includes a pattern of recesses and depressions then the superstrate may sometimes be referred to as a template.

The superstrate 108 may be coupled to or retained by a superstrate chuck assembly 118, which is discussed in more detail below. The superstrate chuck assembly 118 may be coupled to a shaping head 120 which is a part of the positioning system. The shaping head 120 may be movably coupled to a bridge. The shaping head 120 may include one or more actuators such as voice coil motors, piezoelectric motors, linear motor, nut and screw motor, etc., which are configured to move the superstrate chuck assembly 118 relative to the substrate 102 in at least the z-axis direction, and potentially other directions (e.g. x-, y-, θ-, ψ-, and φ-axis).

The shaping system 100 may further comprise a fluid dispenser 122. The fluid dispenser 122 may also be movably coupled to the bridge. In an embodiment, the fluid dispenser 122 and the shaping head 120 share one or more of all positioning components. In an alternative embodiment, the fluid dispenser 122 and the planarization head move independently from each other. The fluid dispenser 122 may be used to deposit droplets of liquid formable material 124 (e.g., a photocurable polymerizable material) onto the substrate 102 with the volume of deposited material varying over the area of the substrate 102 based on at least in part upon its topography profile. Different fluid dispensers 122 may use different technologies to dispense formable material 124. When the formable material 124 is jettable, ink jet type dispensers may be used to dispense the formable material. For example, thermal ink jetting, microelectromechanical systems (MEMS) based ink jetting, valve jet, and piezoelectric ink jetting are common techniques for dispensing jettable liquids.

The shaping system 100 may further comprise a curing system that includes a radiation source 126 that directs actinic energy, for example, UV radiation, along an exposure path 128. The shaping head 120 and the substrate positioning stage 106 may be configured to position the superstrate 108 and the substrate 102 in superimposition with the exposure path 128. The radiation source 126 sends the actinic energy along the exposure path 128 after the superstrate 108 has contacted the formable material 124. FIG. 1 shows the exposure path 128 when the superstrate 108 is not in contact with the formable material 124. This is done for illustrative purposes so that the relative position of the individual components can be easily identified. An individual skilled in the art would understand that exposure path 128 would not substantially change when the superstrate 108 is brought into contact with the formable material 124.

The shaping system 100 may further comprise a camera 136 (also referred to as a spread camera or a field camera) positioned to view the spread of formable material 124 as the superstrate 108 contacts the formable material 124 during the planarization process. FIG. 1 illustrates an optical axis 138 of the field camera's imaging field. As illustrated in FIG. 1, the shaping system 100 may include one or more optical components (dichroic mirrors, beam combiners, prisms, lenses, mirrors, etc.) which combine the actinic radiation with light to be detected by the camera 136. The camera 136 may include one or more of a CCD, a sensor array, a line camera, and a photodetector which are configured to gather light at a wavelength that shows a contrast between regions underneath the superstrate 108 and in contact with the formable material 124 and regions underneath the superstrate 108 but not in contact with the formable material 124. The camera 136 may be configured to provide images of the spread of formable material 124 underneath the superstrate 108, and/or the separation of the superstrate 108 from cured formable material 124. The camera 136 may also be configured to measure interference fringes, which change as the formable material 124 spreads between the gap between the working surface 112 and the substrate surface and as the distance between the working surface 112 and the substrate surface changes.

The shaping system 100 may be regulated, controlled, and/or directed by one or more processors 140 (controller) in communication with one or more components and/or subsystems such as the substrate chuck 104, the substrate positioning stage 106, the superstrate chuck assembly 118, the shaping head 120, the fluid dispenser 122, the radiation source 126, and/or the camera 136. The processor 140 may operate based on instructions in a computer readable program stored in a non-transitory computer memory 142. The processor 140 may be or include one or more of a CPU, MPU, GPU, ASIC, FPGA, DSP, and a general-purpose computer. The processor 140 may be a purpose-built controller or may be a general-purpose computing device that is adapted to be a controller. Examples of a non-transitory computer readable memory include but are not limited to RAM, ROM, CD, DVD, Blu-Ray, hard drive, networked attached storage (NAS), an intranet connected non-transitory computer readable storage device, and an internet connected non-transitory computer readable storage device. All of the method steps described herein may be executed by the processor 140.

In operation, either the shaping head 120, the substrate positioning stage 106, or both vary a distance between the superstrate 108 and the substrate 102 to define a desired space (a bounded physical extent in three dimensions) that is filled with the formable material 124. For example, the shaping head 120 may be moved toward the substrate and apply a force to the superstrate 108 such that the superstrate contacts and spreads droplets of the formable material 124 as further detailed herein.

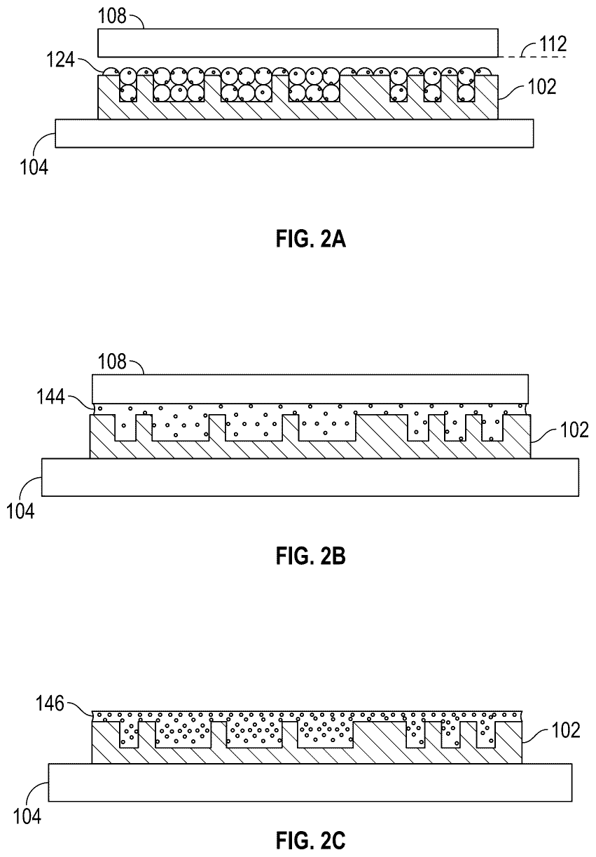

The planarization process includes steps which are shown schematically in FIGS. 2A-2C. As illustrated in FIG. 2A, the formable material 124 is dispensed in the form of droplets onto the substrate 102. As discussed previously, the substrate surface has some topography which may be known based on previous processing operations or may be measured using a profilometer, AFM, SEM, or an optical surface profiler based on optical interference effect like Zygo NewView 8200. The local volume density of the deposited formable material 124 is varied depending on the substrate topography. The superstrate 108 is then positioned in contact with the formable material 124.

FIG. 2B illustrates a post-contact step after the superstrate 108 has been brought into full contact with the formable material 124 but before a polymerization process starts. As the superstrate 108 contacts the formable material 124, the droplets merge to form a formable material film 144 that fills the space between the superstrate 108 and the substrate 102. Preferably, the filling process happens in a uniform manner without any air or gas bubbles being trapped between the superstrate 108 and the substrate 102 in order to minimize non-fill defects. The polymerization process or curing of the formable material 124 may be initiated with actinic radiation (e.g., UV radiation). For example, radiation source 126 of FIG. 1 can provide the actinic radiation causing formable material film 144 to cure, solidify, and/or cross-link, defining a cured planarized layer 146 on the substrate 102. Alternatively, curing of the formable material film 144 can also be initiated by using heat, pressure, chemical reaction, other types of radiation, or any combination of these. Once cured, the cured planarized layer 146 is formed, the superstrate 108 can be separated therefrom. FIG. 2c illustrates the cured planarized layer 146 on the substrate 102 after separation of the superstrate 108. The substrate and the cured layer may then be subjected to additional known steps and processes for device (article) fabrication, including, for example, patterning, curing, oxidation, layer formation, deposition, doping, planarization, etching, formable material removal, dicing, bonding, and packaging, and the like. The substrate may be processed to produce a plurality of articles (devices).

One scheme for minimizing entrapment of air or gas bubbles between the superstrate 108 and the substrate 102 as the formable material 124 droplets spread, merge and fill the gap between the superstrate 108 and the substrate 102 is to position the superstrate 108 such that it makes initial contact with the formable material 124 in the center of the substrate 102 with further contact then proceeding radially in a center to perimeter fashion. This requires a deflection or bowing of the superstrate 108 or substrate 102 or both to create a curvature in the superstrate 108 relative to the substrate 102. The curvature of the superstrate 108 facilitates the expulsion of the air or gas bubbles as the formable material 124 spreads. Such a superstrate 108 profile can be obtained by, for example, applying a back pressure to the interior region of the superstrate. However, in doing so, a perimeter holding region is still required to keep the superstrate 108 retained on the superstrate chuck assembly 118. Given that the superstrate 108 is typically of the same or similar areal dimension as the substrate 102, if both the perimeter edges of the superstrate 108 and the substrate are 102 chucked flat during formable material 124 droplet spreading and merging, there will be no available superstrate curvature profile in this flat chucked area. This may compromise the droplet spreading and merging, which may also lead to non-fill defects in the region. To minimize non-fill defects, the superstrate curvature needs to be controlled over the full superstrate diameter during the fluid spreading process. In addition, once spreading and filling of the formable material is complete, the resultant stack of a superstrate chuck, a chucked superstrate, the formable material, substrate, and a substrate chuck can be an over-constrained system. This may cause a non-uniform planarization profile of the resultant planarized film layer. That is, in such an over-constrained system, all flatness errors or variations from the superstrate chuck, including front-back surface flatness, can be transmitted to the superstrate and impact the uniformity of the planarized film layer. Additionally, at the time of separating the superstrate from the cured film, it is desirable to achieve a consistent circumferential separation front between the superstrate and the cured film.

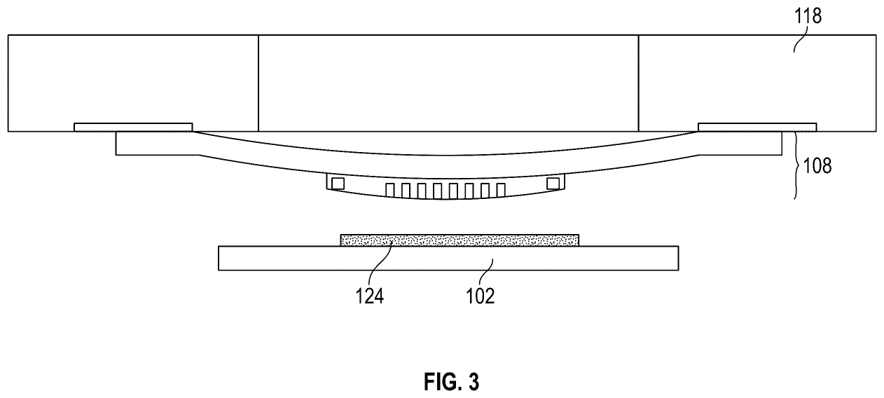

FIG. 3 illustrates a state in which a superstrate 108 (in which the working surface 112 for example has a pattern P) is curved to project toward the substrate 102. As a method of curving the superstrate 108 (surface of the pattern), a method of applying pressure from the superstrate chuck assembly 118 that holds the superstrate 108 is exemplified. A space between the superstrate 108 and the superstrate chuck assembly 118 is a closed space, and the superstrate chuck assembly 118 is provided with a mechanism configured to vary the pressure (air pressure) in the space. The shaping apparatus of the embodiment brings part of the working surface 112 into contact with the formable material 124 on the substrate in a state in which the superstrate 108 is curved as illustrated in FIG. 3. After part of the pattern P has been brought into contact with the formable material 124, the formable material 124 is brought into contact with an entire surface of the pattern P so as to increase the contact surface area between the pattern P and the formable material 124 while straightening the superstrate 108 curved into a convex shape (canceling the curvature). By bringing the superstrate 108 into contact with the formable material 124 in the curved state, air bubbles can hardly be remained in a concave of the pattern P.

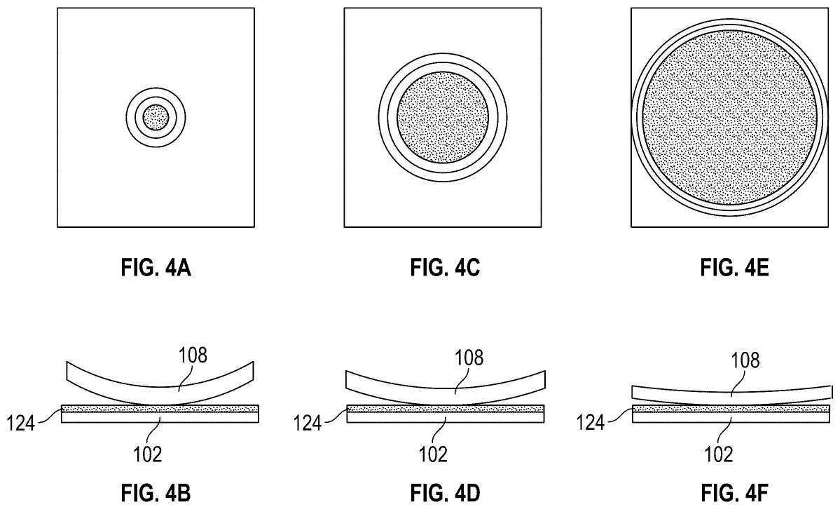

FIGS. 4A to 4F are drawings illustrating the contact state in which the superstrate 108 is brought into contact with the formable material 124 in the curved state. FIGS. 4A to 4F illustrate a state in which no foreign substance (particle) is present between the superstrate 108 and the substrate 102. FIGS. 4A, 4C, and 4E illustrate observed images detected by the camera 136 of the shaping system 100 when bringing the pattern P into contact with the formable material 124, respectively. FIGS. 4B, 4D, and 4F illustrate cross sections of the pattern P and the substrate 102, respectively.

FIG. 4A illustrates a state in which the superstrate 108 is curved (deformed), and the working surface 112 (which may include a pattern P) is brought into a first contact with the formable material 124. The lowest point of the working surface 112 in the convex shape is in contact with the formable material 124. At this time, the observed image observed by the camera 136 includes an area where the working surface 112 and the formable material 124 are in contact with each other (solid area at a center), and an interference fringe caused by interference of light in the periphery thereof. FIG. 4B illustrates a cross section of the pattern P and the substrate 102 at this time.

By straightening the superstrate 108 gradually into a flat surface after the working surface 112 and the formable material 124 have come into contact with each other, a contact surface area between the working surface 112 and the formable material 124 is increased. FIGS. 4C and 4E illustrate a state in which the contact surface area between the working surface 112 and the formable material 124 is increased. A state in which the contact surface area between the working surface 112 and the formable material 124 is uniformly (concentrically) increased from the center of the pattern portion toward the peripheral portion is illustrated.

FIGS. 4D and 4F illustrate cross sections of the pattern P and the substrate 102 corresponding to FIGS. 4C and 4E, respectively. It is understood that the contact surface area between the working surface 112 and the formable material 124 is increased as the curvature of the superstrate 108 (pattern P) is gradually straightened. The interference fringe seen in the periphery of the area where the pattern P and the formable material 124 are in contact with each other is also spread corresponding to the increase of the contact surface area. The interference fringe is generated by interference between light reflected from the working surface 112 and light reflected from the surface of the substrate 102. Finally, the working surface 112 and the formable material 124 come into contact with each other over the entire surface of the shaping area (shot area) (which may be either a whole substrate or a portion of the substrate), the interference fringe is not seen any longer. When the working surface 112 and the formable material 124 come into contact with each other, since there is little difference in refractive index between the superstrate 108 and the formable material 124, light is not reflected by the working surface 112, and hence the intensity variation of the interference fringe is very small and cannot be seen any longer.

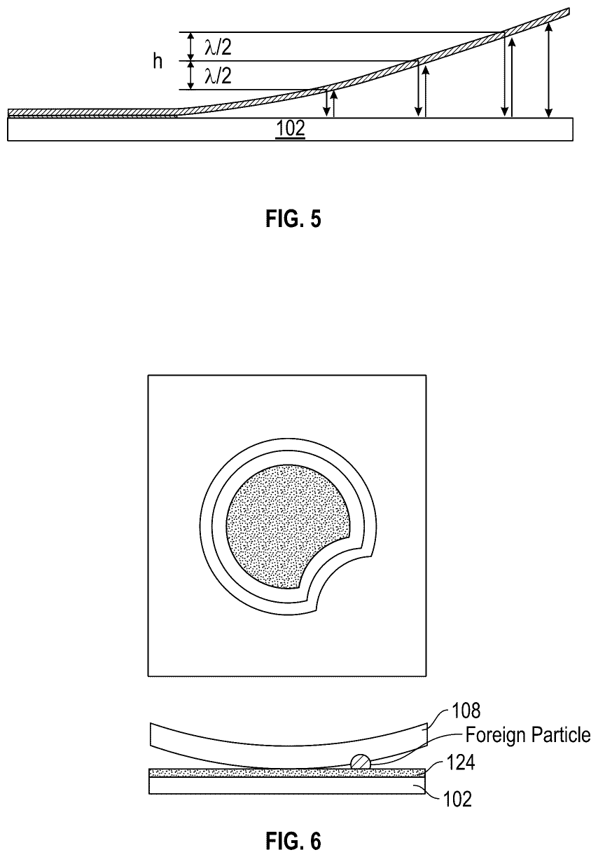

A phenomenon in which the interference fringe due to the interference of light is seen in the periphery of the contact area will be described with reference to FIG. 5. When the superstrate 108 is curved with respect to the substrate 102 and brought into contact with (stamped on) the formable material, illuminating light radiated from the radiation source 126 onto the superstrate 108 and the substrate 102 is reflected by the surface of the substrate 102, and is reflected by the surface opposing the substrate 102 of the superstrate 108. The interference fringe is generated by interference between the reflected light from the substrate 102 and the reflected light from the superstrate 108. The distances at respective positions in a range from the centers of the substrate and the superstrate 108 toward the peripheries thereof is represented by h (h is the distance between template and substrate surfaces), a wavelength of the detection light used in the camera 136 is represented by λ, the order of the interference fringe is represented by m, and a refractive index of medium (for example helium, carbon dioxide, Nitrogen, Air, Argon, etc.) at the wavelength of the detection light between the substrate 102 and the superstrate 108 is represented by n (this is approximately equal to 1 under most circumstances), the conditions of generation of the interference fringe is expressed by

$$2 \times n \times h = ( m + 0.5 ) \times λ : BRIGHT LINE ( m = 0 , 1 , 2 , 3 , … ) \qquad Expression 1$$

$$2 \times n \times h = m \times λ : DARK LINE ( m = 1 , 2 , 3 , … )$$

$$( Destructive interference ( dark fringe ) occurs when 2 \times h = m \times λ , \\ m = 1 , 2 , 3 … )$$

In a portion in which the superstrate 108 and the formable material are in contact with each other, the formable material is present between the superstrate 108 and the substrate 102. As described above, since there is little difference in refractive index between the superstrate 108 and the formable material, not much light is reflected by the surface of the superstrate 108 at the working surface 112/formable material 124 interface. Therefore, the interference fringe is not generated in the area in which the superstrate 108 and the formable material are in contact with each other. A bright and dark ring pattern similar to a Newton's ring (also known as interference fringes), in which several bright and dark rings are repeated in a concentric fashion, appears in the periphery of the contact portion between the superstrate 108 and the formable material 124. The contact state between the formable material 124 and the superstrate 108 is observed by using the interference fringes.

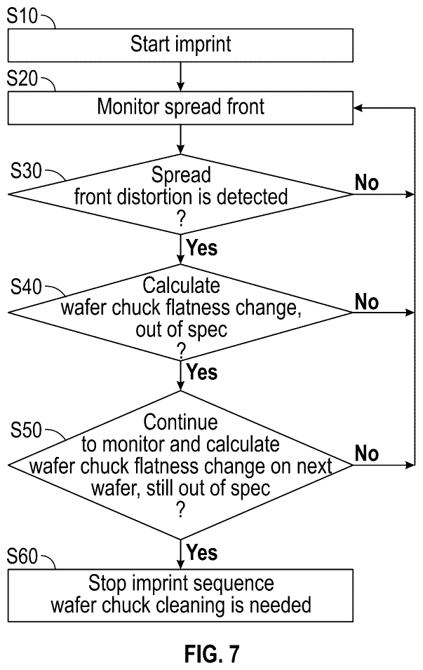

FIG. 6 illustrates an image of a contact area picked up by the camera 136 and the interference fringes in the periphery thereof when a foreign particle is located between the superstrate 108 and the formable material 124.

In FIG. 6, the contact area and the interference fringe generated in the periphery thereof observed when the superstrate 108 and the formable material 124 are brought into contact with each other has a shape deviating from the circular shape (deformed shape). This can be because an air bubble or a foreign substance (for example a particle) is present between the superstrate 108 and the substrate 102. Normally, the distance h (FIG. 5) between the substrate 102 and the superstrate 108 is determined continuously by the amount of deformation of the superstrate 108. Therefore, the contact area and the interference fringe in the periphery thereof spread from the center of the shot area to the peripheral portions in a concentric fashion as illustrated in FIGS. 4A to 4F. However, the interference fringe cannot have a concentric circular shape due to an air bubble or a foreign substance present between the superstrate 108 and the substrate 102. The applicant has found when the superstrate 108 is thin (less than 1 mm), the superstrate will deform around the foreign particle causing interference fringes to appear around the foreign particle after the superstrate makes contact with the formable material around the foreign particle.

As a method of detecting an interference fringe deformed from the concentric circular shape includes using a camera 136 and software to monitor a spread camera image showing spread front distortion. The interference fringes detected by the camera 136 do not directly measure the spread front, but they are correlated with the spread front. During a contact stage of a shaping process a brightness peak of the zero order bright fringe will be slightly outside a distance Δβ₀ in the radial direction of the spread front depending on the angle ψᵣ (typically less than 1°) of the working surface 112 with the substrate 102 in the radial direction and a thickness Δz of the film being formed (Δβ₀=(λ/4−Δz)/tan(ψr)). A similar calculation based on expression 1 above can be used when different fringes are tracked. The working surface 112 and/or the substrate 102 will typically have subwavelength features which will cause consistent but non-uniform scattering of the measurement light that is creating the interference fringes, this will add some noise to the measurement process which can be compensated by averaging. The spread camera image is of the interference fringes detected by the camera 136 when bringing the superstrate 108 and the formable material 124 into contact with each other. In the normal state illustrated in FIGS. 4A to 4F, the circular shape indicating the contact area of the interference fringe does not change. It is also possible to obtain the change of the interference fringe at the time of normal pattern transfer as illustrated in FIGS. 4A to 4F in advance and compare the changes at every pattern transfer. Since deformation of the interference fringe from the concentric circular shape is sensed, calculation of the difference from the interference fringe obtained at a normal shot is conceivable. By the comparison with the pattern at every pattern transfer, the contact state, that is, a time period required for the formable material to spread over the area in which the pattern is formed from the first contact (spreading time) may be obtained. The size of the contact area after a predetermined time period has elapsed from the start of contact at the normal pattern transfer illustrated in FIGS. 4A to 4F may be obtained in advance. Therefore, the result of image picked up by the camera when a predetermined period has elapsed after the first contact and the pattern obtained in advance are compared, and whether the time required for the contact area to spread is short or long may be obtained from the difference in size in comparison with that at the time of normal pattern transfer. If the air bubble remains between the template and the substrate, defective pattern transfer results. Therefore, the corresponding shot or substrate becomes a defective shot or defective planarization. Since the probability of the defective shot or defective planarization may be pointed out in advance, the corresponding shot area or substrate may be intensively inspected at a defect inspection after a shaping process. If the foreign substance is present therebetween, the superstrate 108 may have become damaged, for example, the working surface 112 may be broken by the foreign substance attached to the superstrate 108. If the working surface 112 is transferred to another shot area or another substrate with the foreign substance attached to the superstrate 108, defective transfer patterns or planarization may occur repeatedly.

Therefore, when the contact area and the interference fringe in the periphery thereof detected by the camera 136 are deformed from the concentric circular shape as illustrated in FIG. 6, the shaping process is preferably stopped immediately in order to avoid damage on the superstrate 108 or the substrate 102. However, since a process from the contact between the pattern (superstrate) P and the formable material 124 until the filling of the entire surface of the pattern (superstrate) P with the formable material 124 is performed in a very short time, there may be a case where the shaping process cannot be stopped.

Therefore, when the shaping process cannot be stopped in the course of contact, the foreign substance needs to be removed by replacing the superstrate 108 and cleaning after the pattern transfer or planarization. Since there is a probability that the working surface 112 of the superstrate 108 is broken, inspection of the working surface 112 is also required. By detecting the contact state, necessity of cleaning of the superstrate 108 or inspection of the working surface 112 as above described may be found.

Depending on the case, since the superstrate 108 or the substrate 102 may be curved locally by the presence of the foreign substance, and the interference fringe may be generated around the foreign substance, the foreign substance may be detected by using this phenomenon. Furthermore, the state of formable material 124 supplied (applied) onto the substrate 102 may be detected by observing how the interference fringe spreads. When the amount of supply of the formable material 124 is large, the distance between the superstrate 108 and the substrate 102 is increased, and when the amount of supply of the formable material 124 is small, the distance between the superstrate 108 and the substrate 102 is small. The interference fringe generated differs depending on the distance between the superstrate 108 and the substrate 102. Therefore, by observing the difference in the interference fringes, the cases where the amount of the formable material 124 supplied onto the substrate 102 is large or small may be detected to adjust the amount of supply or the position of supply (distribution) of the formable material 124.

As previously stated, normally, the spread front observed in the interference fringes by the camera 136 should be a circle. However, when the substrate chuck flatness is changed due to a particle of foreign substance, prior to contact the local distance between the working surface 112 and the substrate surface changes. While after the working surface 112 contacts the formable material at a specific location the interference fringes substantially disappear unless there is a particle or foreign substance between the working surface 112 and the substrate surface. In addition, if there is a substantial refractive index difference between the formable material and the superstrate which causes an interference signal to be detectable, a variation in the substrate chuck flatness will not show up as interference fringes if the superstrate is thin enough (<1 mm) to conform to the substrate. This change in local distance leads to a distorted spread front. Such spread front distortion on the camera 136 may be detected by image analysis software executed by the processor 140 to detect locations of outliers. The image analysis software may detect the circular objects in the image, fit the circular objects to perfect circles and calculate the amount of deviation (distortion) of the circular objects from the perfect circles. The image analysis software may also use machine learning methods to identify the positions of one or more interference fringes in each image. The machine learning method may be a neural network. The machine learning method may be an object detection neural network. The objects being identified may be arc segments of an interference fringe. Non-limiting examples of neural networks are: Resnet-32, YOLOX, YOLOR, YOLOv4, YOLOV7, OpenAi CLIP, VGG, DenseNet, Inception GoogLeNet, SqueezeNet, MobileNet, ShuffleNet, R-CNN, Fast R-CNN, Faster R-CNN, Mask R-CNN, Mesh R-CNN, and EfficientNet. The neural network may be trained on labeled image data in which individual pixels are labeled as being part of an interference fringe or not. The image analysis software may identify only bright fringes, only dark fringes or both. The image analysis software may be designed to identify only fringes of one or more specific orders. Once fringes are identified, outliers may be determined by comparing the identified fringes to a series of reference fringes that are known not to have particles by identifying radial deviations to identify pixel locations of outliers.

To calculate the sensitivity of the substrate chuck flatness, one method includes calculating the sensitivity of the fringe spacing to chuck flatness change. For example, a high resolution spread camera with 3000×3000 pixels can be used to monitor the typical template mesa area (30×30 mm). The pixel size is 30,000 μm/3000 pixels=10 μm/pixel. The spacing between adjacent fringes on the spread camera is about 7.5 mm/8 fringes=938 μm by way of example. The image analysis method can for example detect a change or distortion of the spread front ring with a sensitivity of a 2 pixel change. That will be 2×10 μm=20 μm, or 20 μm/938 μm-per-fringe=0.021 fringe change. The light source used by the spread camera may be for example 590 nm wavelength. Between adjacent fringes, the vertical distance between template and wafer surfaces is changed by half of the wavelength which is 590 nm/2=295 nm. Therefore, the 2 pixel sensitivity on spread front distortion on the spread camera represents a sensitivity of substrate chuck flatness of 0.021 fringe change, or 0.021×295 nm=6 nm. This means that a 6 nm wafer chuck flatness change may be detected.

To calculate the substrate chuck flatness change, the following equation can be used:

$$\begin{matrix}wafer chuck flatness change ( nm ) = spread front distortion ( pixels ) \times \\ camera pixel size ( \frac{um}{pixel} ) \\ \div fringe spacing ( \frac{um}{fringe} ) \times \\ \frac{1}{2} wavelength ( nm )\end{matrix}$$

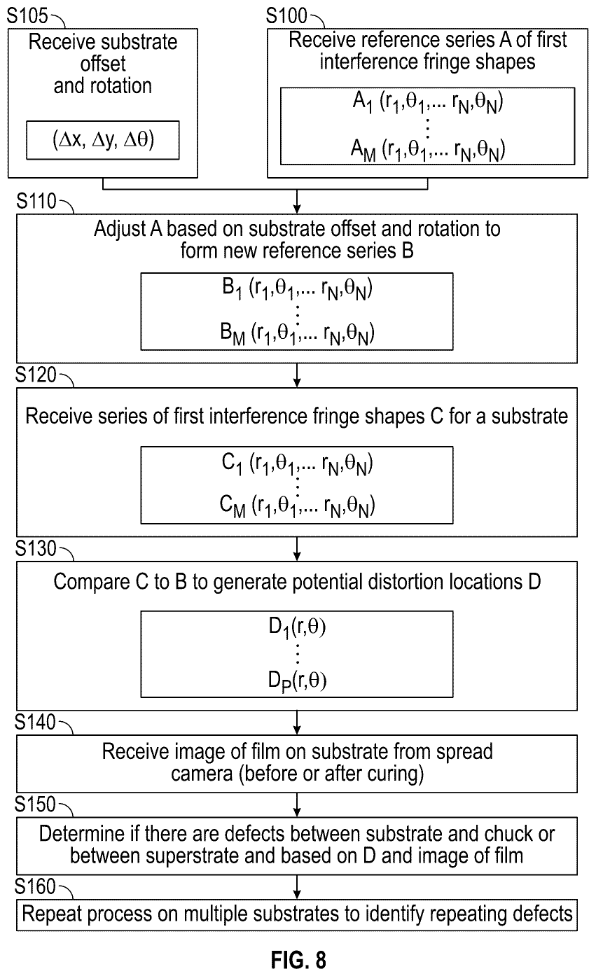

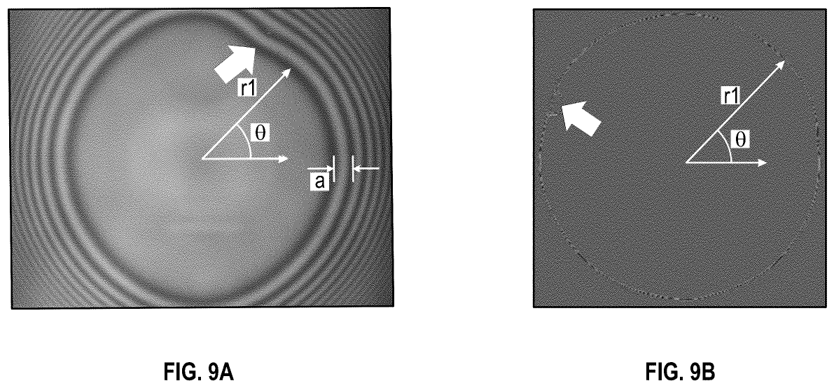

A method of detecting a foreign substance attached below the substrate W will be described with reference to the flowchart of FIG. 7. The initial step includes starting the shaping process in step S10. Subsequently, in step S20, the spread front is monitored by the camera 136 to observe any spread front distortion in the interference rings. Observing spread front distortion in the images in real-time enables the detecting of a change in flatness of a substrate chuck 104 during the shaping process. The change in flatness of the substrate chuck may also be detected after the shaping process by observing recorded spread front images. In step S30, it is determined whether any spread front distortion is detected. If spread front distortion among the spread front is not detected, the process returns to step S20 of monitoring the spread front. Alternatively, if spread front distortion is detected, a change in the substrate chuck flatness is calculated and determined if it exceeds a predetermined threshold in step S40. Step S40 is further described in detail with respect to the flowchart of FIG. 8. In step S40, if it is determined that a change in the substrate chuck flatness does not exceed the predetermined threshold, the process returns to step S20. Alternatively, if it is determined that a change in the substrate chuck flatness exceeds the predetermined threshold, the method continues to step S50. Monitoring the spread front is allowed by obtaining multiple spread front image sequences containing interference fringes that appear during a film shaping process for a series of substrates.

In step S50, the method continues to monitor spread front distortion and calculate the substrate chuck flatness change on the next substrate, to determine if it also exceeds the predetermined threshold associated with the substrate. If it is determined in step S50, that the substrate chuck flatness change on the next substrate does not exceed the predetermined threshold, the method returns to step S20. Alternatively, if the substrate chuck flatness change exceeds the predetermined threshold for the next substrate, the method continues by stopping the shaping sequence in step S60 to clean or replace the substrate chuck in order to remove the particle or impurity. In other words, it is determined that a corrective action should be applied to the substrate chuck when there are repeating outliers at similar locations across multiple substrates from the series of substrates.

The flowchart illustrated in FIG. 8 will now be described with respect to calculating the substrate chuck flatness change determined in step S40 of FIG. 7. In step S100, the method may initiate by receiving reference series A of first interference fringe shapes corresponding to a first wafer undergoing the shaping process. The camera 136 from FIG. 1 may be used to monitor the spread front in a series of images that when combined result in a video sequence. Thus, the series of images may be labeled from a time starting at 1 to the length of the series M. Along with the time for every reference series A, the radius r₁ to r_{N} and the angle θ₁ to θ_{N} associated with the radius for every reference image from the reference series A is included. Since the spread front distortion of the interference fringes correspond to locations of outliers, it is informative to use the radial distances to determine the precise locations of the outliers. The angles θ₁ to θ_{N} are central angles where the vertex is at the center of a concentric circle if no spread front distortion exists. The sides of the angle lie on two radii of the circle. The measure of the central angle is the same as the measure of the arc that the two sides cut out of the circle. Each image can include multiple substantially circular interference fringes or arc segments. Each interference fringe will typically have some deviation from circularity (often referred to as roundness or eccentricity). In the present context substantially circular means having radial of 1-10%. In an embodiment, reference series A includes one or more of: the zero order bright fringe; a first order bright or dark fringe; a gap between two adjacent fringes; a gap between two dark fringes; a gap between two bright fringes; a gap between two specific fringes; multiple bright fringes; multiple dark fringes; and multiple bright and dark fringes.

The reference series A was created with a first substrate 102a that was loaded onto the substrate chuck at a first placement position. A new substrate 102c will then be loaded onto the substrate chuck 104 is at a second placement position that can be slightly different from the first placement position. Next, in step S105, the method includes receiving a substrate offset and rotation value (Δx, Δy, Δθ) which is then used in step S110 to adjust reference series A based on the substrate offset and rotation to form new reference series B. The substrate offset and rotation value represent a difference between the first placement position and the second placement position. This slight difference is within the placement error of the substrate loading system of the shaping system 100 which can be compensated for by adjusting the position of the substrate chuck 104 with the substrate positioning stage 106. Also, when the working surface 112 is much smaller than the substrate and the shaping system 100 is used in a step and repeat manner, each shot will have a different position. Step S110 is performed such that new reference series B is representative of the distortion due the substrate chuck with the new substrate 102c at the second placement position. In an embodiment, steps S105 and S110 are skipped and reference series A and B are identical.

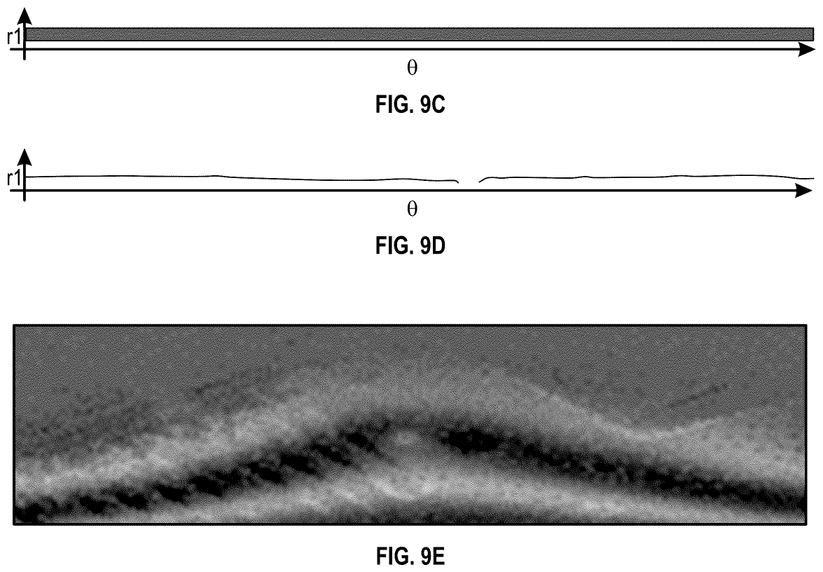

Referring to FIG. 9A, a diagram illustrating an image where spread front distortion is visible as shown by the large arrow referring to the distorted spread front in a nanoimprint lithography system. In this image, an angle θ corresponding to a first radius r₁ is shown as well as a distance a between the first and second interference fringes. Thus, calculating the radius at different angles for a video taken over a time 1 to M will reveal shorter radiuses where the spread front distortion exists as well as the angles at which the spread front distortion occurs. The angle θ may be any angle from 0 to 360 degrees. The measurements of multiple radiuses are taken at incremental values for 0. Referring to FIG. 9B, a video illustrating a spread front in an inkjet adaptive planarization system. FIG. 9B is a predicted video frame in which a reference frame was subtracted from a video frame to produce the frame shown in FIG. 9B. FIG. 9C is annular cropping of the interference fringes and transformed into polar space (r₁,θ). FIG. 9D is an illustration of a line fitted to the interference fringes. The break in the line is where a large particle was detected. FIG. 9E is an illustration of the impact of a smaller particle on a zoomed in portion of another interference fringe. The particle will typically cause a bend in the interference fringe that has a larger deviation than the typical curvature of the interference fringe. A peak or a break in the graph may indicate where the spread front distortion exists. The interference fringes are non-concentric portions in the image of FIGS. 9A-E surrounding locations close to similar locations in final images obtained after a film is shaped on the substrate by contacting a liquid with a shaping surface such as a superstrate. Some spread front distortion is okay and expected due to substrate and pattern non-uniformity. Unexpected spread front distortions that are beyond expected values can be indicative of cleanliness issues either on the superstrate or the substrate.

Referring back to FIG. 8, after step S110 of adjusting references series A images based on the wafer offset and rotation to form new reference series B (B₁ (r₁, θ₁, . . . r_{N}, θ_{N}) to B_{M} (r₁, θ₁, . . . r_{N}, θ_{N})), the next step S120 includes receiving a series of first interference fringe shapes C for a new substrate. A new substrate is placed on the substrate chuck and the processor 140 is configured to receive reference series C (C₁ (r₁, θ₁, . . . r_{N}, θ_{N}) to C_{M} (r₁, θ₁, . . . r_{N}, θ_{N})) of first interference fringe shapes for the new substrate. Next, in step S130, interference fringe shapes C from the new wafer are compared to the interference fringe shapes B of the previous wafer to generate potential distortion locations D. The distortion locations being based on the radius and angle at which the spread front distortion occurs from a first distortion location to P distortions (D₁ (r, θ) to D_{P} (r, θ)). In the next step S140, the method proceeds by receiving an image of film on the substrate from the spread camera (before or after curing). In step S150 using the received image of film on the substrate and the distortion locations D, it is determined if there are defects between the substrate 102 and the substrate chuck 104 or between the superstrate 108 and the formable material film 144 or the cured planarized layer 146. Then in step S160 the process is repeated on multiple substrates to identify repeating defects. If the defect keeps appearing, it is indicative that a foreign particle is located between the substrate and the substrate chuck.

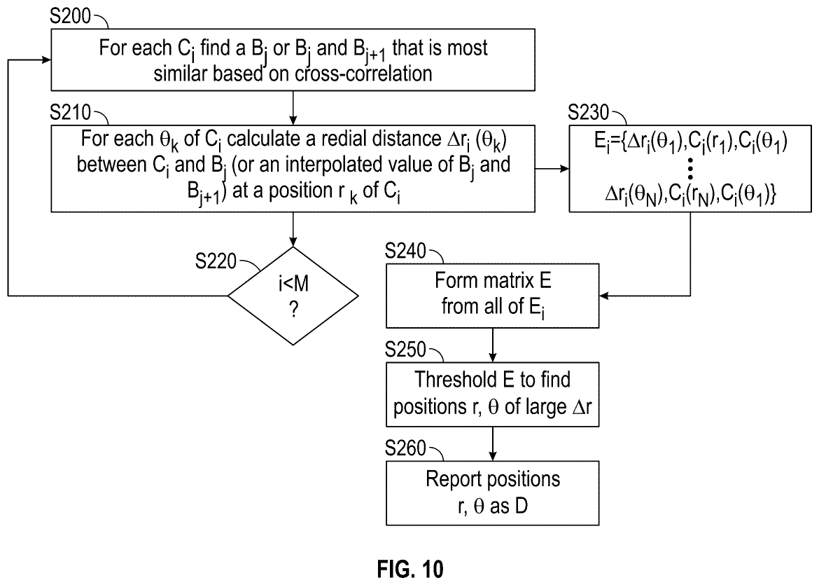

The step S130 in FIG. 8 for comparing the series of first interference fringe shapes C for a second substrate to the reference series B to generate potential distortion locations D is explained in further detail with respect to FIG. 10. In step S200, for each interference fringe series Cᵢ find an interference fringe series Bⱼ or Bⱼ and Bⱼ₊₁ that is most similar is determined. One method of determining which interference fringe is most similar may be based on cross-correlation. Another method is to calculate a radial distance Δr_{i,j} (θₖ) as a function of each angle θₖ at the angles θ₁ to θ_{N} between each interference fringe series Cᵢ and the interference fringes Bⱼ in the reference series B. The radial difference Δr_{i,j}(θₖ) may then be averaged over θₖ to determine an average radial difference (Δ̅r̅_{i,j}) between each interference fringe series Cᵢ and an interference fringe series Bⱼ. The interference fringe series Bⱼ or Bⱼ and Bⱼ₊₁ that have the minimum average radial differences are then selected for each interference fringe series Cᵢ. Another method of determining which fringe is most similar is comparing for each fringe, a radius averaged across multiple angles θ. Another method of determining which fringe is most similar is to use curve fitting techniques such as chi-square minimization. In a first embodiment, only fringes that have the same order and are bright or dark fringes are compared to each other. In a second embodiment, only dark fringes are compared to dark fringes across all orders m. In a second embodiment, only bright fringes are compared to bright fringes across all orders m. In a third embodiment, bright and dark fringes are compared to bright and dark fringes across all orders m. Next in step S210, for each angle θₖ of Cᵢ, calculate a radial distance Δr_{i,j} (θₖ) between Cᵢ and Bⱼ (or an interpolated value of Bⱼ and Bⱼ₊₁) at a position rₖ of Cᵢ for the time i<M at step S220. Next, in step S230 a threshold value Eᵢ is determined. In step S240 a matrix E is formed from all of Eᵢ. In step S250, threshold E is used to find positions r, θ of large radial distances Δr. In step S260, the positions of r and θ that are equal or exceed the threshold E are reported as distortion positions D.

A method of manufacturing an article (semiconductor integrated circuit device, liquid crystal display device, and the like) as an article includes a process of forming a pattern and/or planarizing on a substrate (wafer, glass plate, template, and film wafer) by using the shaping system 100 described above. In addition, the manufacturing method described above may include a process of etching the substrate on which a pattern is formed. In a case of manufacturing other articles such as patterned media (recording media) or optical devices, the manufacturing method may include other processes which machine the substrate on which the pattern is formed instead of etching. The method of manufacturing an article of the embodiment is advantageous in terms of at least one of performance, quality, productivity, and production cost or articles in comparison with the method of the related art. The article produced by the method of manufacturing is an article that is manufactured on or from the substrate using a plurality of processes. Non-limiting examples of such an article include: an electrical circuit element, an optical element, a microelectromechanical system (MEMS), a recording element, a sensor, a mold, a template, an integrated circuit, a power transistor, a charge coupled-device (CCD), an image sensor, a microfluidic device, or the like. The method of manufacturing an article can include multiple processes such as semiconductor manufacturing processes. Well known semiconductor processing steps can be used in the method of manufacturing an article. Non-limiting examples of such semiconductor processes which can be performed in method of manufacturing an article include: inspection, curing, oxidation, layer formation, patterning, developing, cleaning, deposition, doping, planarization, etching, formable material removal, testing, singulating, bonding, and packaging.

While the present disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

The above-described exemplary embodiments are merely specific examples for carrying out the present disclosure. The technical scope of the present disclosure should not be interpreted in a limited way due to these embodiments. The present disclosure can be carried out in various forms without departing from the technical idea or the main features thereof. For example, any combination of the exemplary embodiments is also included in the disclosed contents of the present disclosure.

Further modifications and alternative embodiments of various aspects will be apparent to those skilled in the art in view of this description. Accordingly, this description is to be construed as illustrative only. It is to be understood that the forms shown and described herein are to be taken as examples of embodiments. Elements and materials may be substituted for those illustrated and described herein, parts and processes may be reversed, and certain features may be utilized independently, all as would be apparent to one skilled in the art after having the benefit of this description.

What is claimed is:

1. A method for monitoring substrate chuck flatness by monitoring a spread front using a spread camera to detect a change in flatness of a substrate chuck, the method comprising:
obtaining multiple fluid spread image sequences containing interference fringes that appear during a film shaping process performed on a series of substrates;
determining locations of outliers based on radial distances of the interference fringes for each substrate from the series of substrates; and
applying a corrective action to the substrate chuck when there are repeating outliers at similar locations across multiple substrates from the series of substrates.

2. The method of claim 1, wherein the corrective action is one or more of: replacing, cleaning, or polishing the substrate chuck.

3. The method of claim 1, further comprising, applying the corrective action, when the interference fringes are non-concentric surrounding locations close to the similar locations in final images obtained after a film is shaped on the substrate by contacting a liquid with a shaping surface.

4. The method of claim 1, wherein the interference fringes are caused by interference of reflected light obtained by the spread camera, wherein a location of a dark fringe is determined by a wavelength of the reflected light and a distance between a shaping surface used in the film shaping process and the substrate.

5. The method of claim 1, wherein the radial distances of the interference fringes are determined for a plurality of different angles of a circle ranging from 0 to 360 degrees.

6. The method of claim 1, wherein the radial distances of the interference fringes are determined from a period of time initiating at a start of the film shaping process until the spread front has reached an edge of an area of interest for all angles.

7. The method of claim 1, wherein the radial distances are adjusted to take into account a substrate offset and a substrate rotation relative to the substrate chuck.

8. The method of claim 6, further comprising:
comparing the radial distances of the interference fringes from two different substrates from the series of substrates to determine the locations of outliers.

9. The method of claim 8, further comprising:
receiving an image of a film on the substrate and underneath the superstrate from the spread camera before or after curing of the film; and
determining locations of defects between the substrate and the substrate chuck by analyzing the image of the film at the locations of outliers.

10. The method of claim 9, further comprising determining if the locations of outliers exist between a shaping surface and the film by analyzing the image of the film.

11. The method of claim 9, wherein when the locations of outliers are detected from multiple sequential substrates from the series of substrates, it is notified that the locations of outliers are defects associated with contamination of the substrate chuck.

12. The method of claim 8, further comprising:
comparing the radial distances of the interference fringes from two different substrates at similar periods of time determined by cross-correlation to determine a location outlier.

13. The method of claim 12, wherein the location outlier is compared to a threshold value, wherein when the threshold value is exceeded the radial distance and angle of the location outlier is determined to be a position of a distortion in the interference fringe.

14. The method of claim 1, further comprising:
calculating a substrate chuck flatness change using the following equation: wafer chuck flatness change (nanometers)=(spread front distortion (pixels)×camera pixel size (micrometers/pixel))×½ (wavelength) (nanometers) divided by (fringe spacing (micrometers/fringe)).

15. The method of claim 14, wherein the spread camera is a high-resolution camera configured to monitor one of: a template mesa area of approximately 30×30 millimeters and a pixel size is approximately 10 micrometers/pixel; and a superstrate area with a 300 mm diameter and the pixel size is approximately 60 micrometers/pixel.

16. The method of claim 14, wherein the spread camera and image analysis software is configured to detect a substrate chuck flatness change as small as 6 nanometers.

17. The method of claim 1, further comprising:
manufacturing one or more articles, wherein manufacturing the one or more articles includes:
depositing drops of formable material on the substrate;
bringing a shaping surface of one of a superstrate and a template into contact with the formable material that has been deposited on the substrate;
after bringing the shaping surface into contact with a fluid that has been deposited on the substrate, curing the formable material that has been deposited on the substrate; and
after curing the formable material that has been deposited on the substrate, processing the substrate so as to manufacture the one or more articles.

18. The method of claim 1, wherein the radial distances are relative to one of:
a substrate center; and
an initial contact point of a shaping surface with a film formed on the substrate.

19. The method of claim 1, wherein the multiple substrates are multiple sequential substrates.

20. The method of claim 1, further comprising:
inspecting one or both of:
a cured film formed on a substrate among the multiple substrates formed with the film in the film shaping process at the determined location of the outlier; and
the substrate chuck at the determined location of the outlier,
wherein the corrective action is determined based on results of the inspection of the cured film.

21. The method of claim 1, wherein the film shaping process is performed using more than one shaping surface on different substrates, wherein the corrective action is determined based on results of the inspection of the cured film.

22. A device for monitoring substrate chuck flatness by monitoring a spread front to detect a change in flatness of a substrate chuck in real time, the device comprising:
a spread image camera to obtain multiple fluid spread image sequences based on interference fringes that appear during a film shaping process for a series of substrates;
one or more computer-readable storage media; and
one or more processors that are in communication with the one or more computer-readable storage media and that cooperate with the one or more computer-readable storage media to cause the device to perform operations comprising:
determining locations of outliers based on radial distances of the interference fringes for each substrate from the series of substrates; and
applying a corrective action to a substrate chuck when there are repeating outliers at similar locations across multiple substrates from the series of substrates.
